(19) United States
(12) Patent Application Publication
(10) Pub. No.: US 2017/0214361 A1
(43) Pub. Date: Jul. 27, 2017

(54) SOLAR CELL CURRENT AND VOLTAGE CHARACTERISTIC MEASUREMENT

(71) Applicant: Beamreach Solar, Inc., Milpitas, CA (US)

(72) Inventors: Daniel E. McDermid-Grupp, Milpitas, CA (US); Pavit Singh, San Jose, CA (US)

(21) Appl. No.: 15/250,895

(22) Filed: Aug. 29, 2016

Related U.S. Application Data
(60) Provisional application No. 62/211,622, filed on Aug. 28, 2015.

(51) Int. Cl. H02S 50/10; G01R 31/40

(52) U.S. Cl. CPC H02S 50/10; G01R 31/40

(57) ABSTRACT

A method for measuring the current and voltage IV characteristics of a solar cell, comprising attaching a solar cell to a temperature controlled chuck. Measuring the open circuit voltage of the solar cell at a constant chuck temperature. Illuminating the solar cell using an illumination source. Measuring the open circuit voltage of the solar cell until the open circuit voltage is stable. Determining the peak open circuit voltage of the solar cell at the constant chuck temperature. Reducing the temperature of the temperature controlled chuck and measuring the open circuit voltage of the solar cell until the open circuit voltage is at the peak open circuit voltage. Measuring the current and voltage IV characteristics of the solar cell.

### CROSS-REFERENCE TO RELATED APPLICATIONS

This application claims the benefit of U.S. provisional patent application 62/211,622 filed on Aug. 28, 2015, which is hereby incorporated by reference in its entirety.

### FIELD OF THE INVENTION

The present disclosure relates in general to the fields of solar photovoltaics (PV), and more particularly to solar PV cells.

### BACKGROUND

The current and voltage output characteristic (IV curve) of a solar cell are measured as an indicator of solar cell performance. Various parameters such as the open-circuit voltage (Voc), the short-circuit current (Isc), and the efficiency (E) may be extracted from the IV curve—parameters which to some degree are sensitive to temperature. Often measurements are performed over a period of time during which the solar cell is illuminated. During this measurement time, the solar cell may heat up. Attempts are often made to stabilize the temperature of the solar cell. However, even if the temperature of the solar cell is known at the start of the measurement (e.g., before an illumination light is turned on), the temperature may drift during the measurement, thus resulting in inaccurate results. Additionally, it may be difficult to know the precise temperature of the solar cell during the measurement as measuring instruments may interfere with the illumination and temperature measurement in the presence of a heat source may be challenging as the probe itself may heat up differently than the cell itself, thus leading to lack of clarity as to what exactly is being measured. Additionally, the block or chuck upon which the solar cell may rest, for example a temperature controlled chuck, may be at a different temperature than the solar cell resting upon it due to a potentially limited ability to thermally anchor the solar cell to the block or chuck. Thus it is challenging to determine the temperature of the solar cell precisely, especially between measurements, so that different solar cells, in particular from the same solar production line but perhaps with different process parameters or over different runs for statistical process control, may be compared with high discrimination.

### BRIEF SUMMARY OF THE INVENTION

Therefore, a need has arisen for improved temperature accuracy solar cell current and voltage IV characteristic measurements. In accordance with the disclosed subject matter, improved temperature accuracy solar cell current and voltage IV characteristic measurements are provided which may substantially eliminate or reduces disadvantage and deficiencies associated with previously developed solar cell current and voltage IV characteristic measurements.

According to one aspect of the disclosed subject matter, a method for measuring the current and voltage IV characteristics of a solar cell is provided. The method comprises attaching a solar cell to a temperature controlled chuck. Measuring the open circuit voltage of the solar cell at a constant chuck temperature. Illuminating the solar cell using an illumination source. Measuring the open circuit voltage of the solar cell until the open circuit voltage is stable. Determining the peak open circuit voltage of the solar cell at the constant chuck temperature. Reducing the temperature of the temperature controlled chuck and measuring the open circuit voltage of the solar cell until the open circuit voltage is at the peak open circuit voltage. Measuring the current and voltage IV characteristics of the solar cell.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings (dimensions, relative or otherwise not drawn to scale) in which like reference numerals indicate like features and wherein:

FIG. 2 is an exemplary graph of Voc vs Time showing a voltage characteristic produced by a solar cell; and,

FIG. 2 is an exemplary graph of Voc vs Time showing an exemplary extrapolation.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like aspects and identifiers being used to refer to like and corresponding parts of the various drawings.

And although the present disclosure is described with reference to measurement embodiments such as voltage and Voc, fabrication and installation processes, and materials, one skilled in the art could apply the principles discussed herein to other measurement embodiments such as current and Isc, fabrication and installation processes, as well as alternative technical areas and/or embodiments without undue experimentation.

The comprehensive solution for solar cell current and voltage characteristic measurement provided may be used to accurately determine and control the temperature of a solar cell during measurement to measure the current and voltage characteristics of a solar cell under constant temperature. The comprehensive solution for solar cell current and voltage characteristic measurement provided may utilize a thermally controlled block or chuck upon which a solar cell may be mounted with a stable thermal conductance, an illumination source with a rapid shutter, and a solar cell voltage measurement system electrically connected to positive and negative solar cell terminals for rapidly measuring and recording the open-circuit voltage of the solar cell. Bring the solar cell to an equilibrium temperature wherein the solar cell is at the same temperature as the chuck that supports it. Advantageously, this may require the chuck to be at a temperature close to the ambient temperature. Thus, at equilibrium all parts of the system and surrounding ambient (i.e., chuck, solar cell, air) are at the same temperature such that measuring the chuck temperature is an accurate measurement of the solar cell temperature. A continuously-recorded Voc measurement is initiated and then the illumination source shutter is opened. Advantageously, the shutter opening time should be less than the time the solar cell takes to reach full Voc. The shutter then remains open until Voc is determined to be stable, in other words the Voc is not varying with time. The curve of the graph of the Voc vs Time will show a sharp rise to a peak, followed by a decline, followed by a flat stable region—for example as shown in the exemplary graph of Voc vs Time of FIG. 1 showing a voltage characteristic produced by a solar cell when opening a shutter with the solar cell on a temperature-stabilized chuck. This may be explained as follows: the first rising region is dominated by the illumination of the solar cell as it develops its full voltage; the falloff from the peak is an indication that the solar cell is heating up; and, the flat region is an indication that the solar cell has reached an equilibrium temperature.

Once the voltage characteristic curve is determined, parameters may be extracted to allow for a temperature-stabilized measurement of the solar cell. The next step is to determine the Voc at the peak of the curve. This value is used a measure of the Voc of the cell at the initial temperature of the chuck. As Voc is temperature-sensitive, Voc itself may now be used as a thermometer for the cell to determine the cell temperature over time. The next step is to adjust the chuck temperature (by lowering the chuck temperature) while measuring the Voc until the Voc measured for the solar cell returns to the value measured at the peak. The temperature at which this occurs is the new temperature set point for the chuck. While it may be lower than the original temperature, the solar cell itself is now at the original (pre-shutter open) temperature. Once this is achieved, the solar cell may now be determined stably at the known initial temperature of the chuck, and a measurement of the IV characteristic may be measured where the complete curve is known to be with the solar cell at the same, constant, and known temperature.

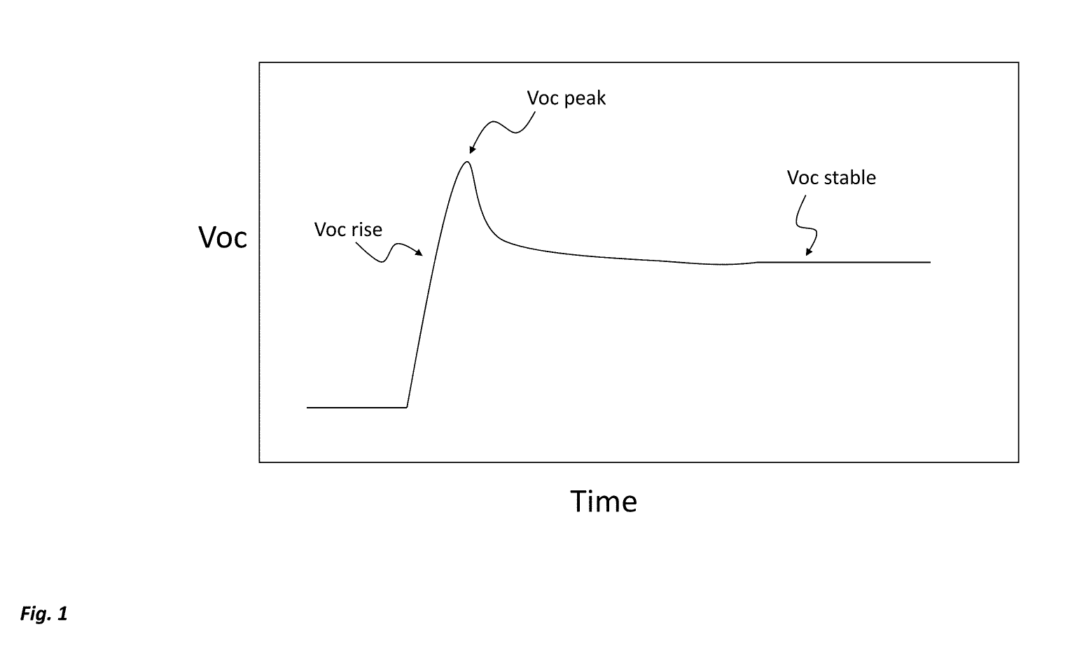

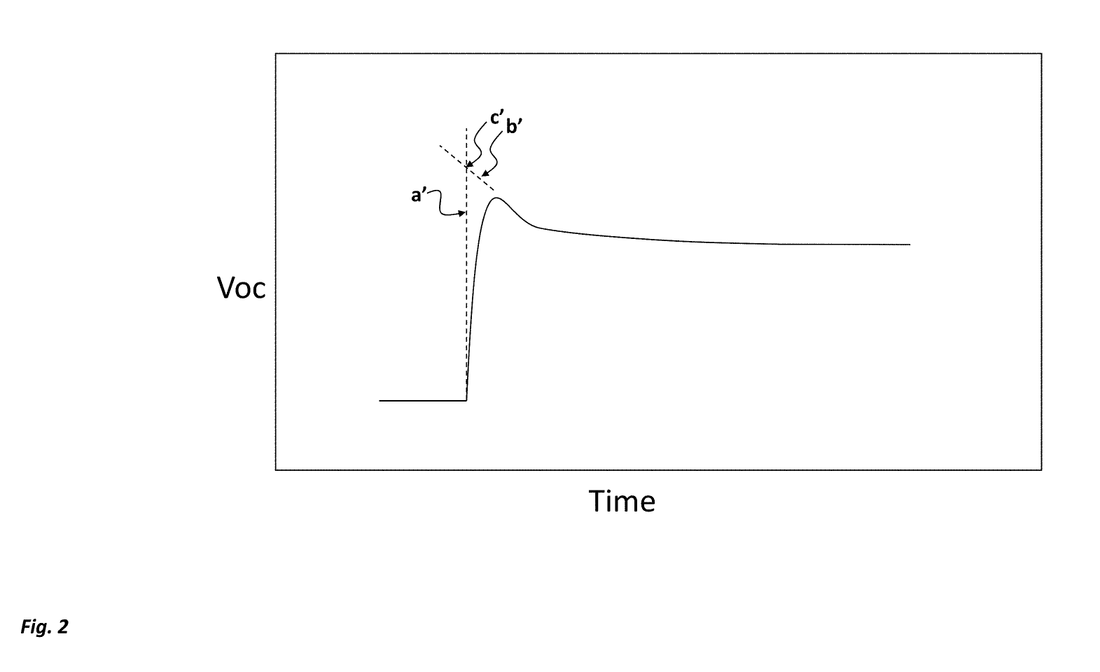

Corrections may be made by noting that the temperature may rise from the time the shutter opens until the peak is reached. Various approximations may be used to extrapolate by how much the cell must have heated during this time—FIG. 2 is an exemplary graph of Voc vs Time of a voltage characteristic similar to FIG. 1 and showing an exemplary extrapolation backwards in time to approximate heating during turn-on of the solar cell. Using this method, a line is fit to the downside of the peak open circuit voltage just after the peak to the stable open circuit voltage (shown as extrapolation b′ in FIG. 2) and followed backwards to the time the shutter was opened (shown as shutter opening a′ in FIG. 2) to determine an adjusted peak open circuit voltage (shown as peak open circuit voltage c′ at the intersection of a′ and b′ in FIG. 2). This voltage value may be used. Care must be taken to include mechanical effects in the rise, such as the widening of the shutter opening that results in an illumination that increases as the shutter is opened and thus contributes to the rise towards the peak. Hence an advantageous method is one in which it is determined that the shutter opens sufficiently rapidly such that the rise is predominantly due to the turn-on of the solar cell under full illumination. For example, the shutter opening time may be less than 10% of the time for the peak to develop. The characteristic turn-on time of solar cells is from 10-100 milliseconds. Thus, a shutter advantageously faster than 10-100 milliseconds may be selected depending on the particular solar cell.

Using the method provided it may be possible to achieve repeatable measurements of Voc with an error, preferably, less than one millivolt for a solar cell generally possessing a Voc with a range of 650-700 mV. Additionally, using the method provided a repeatable Voc measurement of less than 0.5 millivolts, or preferably less than 0.25 mV, may be achieved. As a commercial advantage, a one mV change in Voc on a high-performing commercially available solar cell results in roughly 0.05% increase in efficiency, which is a useful level for being able to distinguish the effects of process changes, especially as while that magnitude may not be commercially significant, determining which direction a process change moves the output parameters is valuable and the ability to determine such small changes in aggregate may yield large valuable output changes of, for example 0.5%, absolute efficiency improvement.

Additionally, the method provided takes account of the inability to perfectly thermally anchor a solar cell to a chuck. There often may be a general thermal impedance between the chuck and the solar cell such that when a heat load is input to the solar cell, the temperature will rise above that of the chuck by an unknown and difficult to predict amount. Using the method provided, it is not necessary to know this thermal impedance or to know the temperature at which a cell will rise to when illuminated. Thus, the method provided may be particularly useful for solar cells that possess an insulating layer at the back (non-illuminated) side of the solar cell, such as some versions of back-contacted solar cells. For such cells, the silicon cannot be directly contacted and the thermal anchoring may be difficult.

It may also not be necessary to measure the region of the Voltage vs. Time curve where the voltage output is flat. It is generally only necessary to measure a peak in the curve, and then to use that peak value, or an extrapolation from that peak. However, the method provided may depend on such a flat region existing so that it is known that the system will achieve a dynamic equilibrium wherein the solar cell is at a constant temperature higher than the chuck at a lower constant temperature. An example where this method would not generally be applicable is one in which the thermal impedance from the solar cell to the chuck changes with temperature such that the solar cell, for example, may continue to heat. Thus a method which is effective at achieving a temperature stabilized measurement of a solar cell IV characteristic might consist of measuring the Voltage vs Time curve at least once to determine that for the particular system configuration (type of chuck and thermal contact method and type of solar cell) a thermal equilibrium exists, and then subsequent measurements may proceed by performing the Voltage v Time curve only so long as needed to detect a peak after the shutter is open. This method may shorten the needed measurement time for multiple measurements of a series of solar cells. It may be advantageous in this shortened method to perform a series of tests with the same or different solar cells to determine that the offset temperature (i.e., the difference between the initial stable temperature and the stable temperature under illumination) is within an acceptable range of variation.

The method of temperature control of a chuck may be performed using known negative feedback or PID control methods utilizing a temperature sensor embedded in the chuck and a means of heating or cooling the chuck, such as Peltier coolers. The method of adjustment of the chuck temperature to achieve a Voc of the peak Voc may also be performed using known feedback methods where the chuck coolers and heaters are controlled using the voltage input from the solar cell. After a steady value at the peak Voc has been achieved, control of the chuck may be advantageously returned to using the temperature sensor of the chuck as the input sensor to the controller, where the set point is determined prior to changing control methods once the Voc has been determined to be suitably stable with the temperature of the chuck being read and recorded at that point.

In some instances, for example depending on cell type, it may be advantageous to measure the voltage at intervals of 2 ms or faster.

And importantly, the shutter is a means to open and close access to a light source that is stable (i.e., continuously on).

An additional advantage of the method provided is the rapid measurement of Voc using a temperature controlled chuck and a shutter whose time to completely open is less than the turn-on time of the solar cell, advantageously with the shutter opening time less than about 10% of the turn-on time. Imperfect thermal anchoring may be accounted for by methods of extrapolating backwards in time on the output Voltage vs Time curve. For measuring only the Voc precisely, a flash lamp with a rapid rise to a steady value may also be used instead of a shutter to a stably on source.

For measuring a complete IV curve, a flash lamp with a stable value after turn-on may also be used if it may be determined that there is a stable region of output voltage while the lamp is on (e.g., a stable region as shown as the stable region after the peak in FIG. 1).

In operation, key aspects of the method provided include, but are not limited to: with a shutter faster than the turn-on of a solar cell, the Voc of a solar cell may be rapidly measured and then Voc of the solar cell itself used as a thermometer, Voc may then be used to set the temperature of a chuck, and then a temperature stable measurement may be performed with high repeatability and precision.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A method for measuring the current and voltage IV characteristics of a solar cell, comprising:
attaching a solar cell to a temperature controlled chuck;
measuring the open circuit voltage of said solar cell at a constant chuck temperature;
illuminating said solar cell using an illumination source;
measuring the open circuit voltage of said solar cell until the open circuit voltage is stable;
determining the peak open circuit voltage of said solar cell at said constant chuck temperature;
reducing the temperature of said temperature controlled chuck and measuring the open circuit voltage of said solar cell until the open circuit voltage is at said peak open circuit voltage; and,
measuring the current and voltage IV characteristics of said solar cell.

2. The method of claim 1, wherein said step of determining the peak open circuit voltage of said solar cell at said constant chuck temperature further adjusting the measured peak open circuit voltage of said solar cell using a linear fit of the open circuit voltage between the measured peak open circuit voltage and the measured stable open circuit voltage.
